(19) United States
(12) Patent Application Publication
(10) Pub. No.: US 2009/0066303 A1
(43) Pub. Date: Mar. 12, 2009

(54) VOLTAGE REGULATOR WITH TESTABLE THRESHOLDS

(75) Inventors: Ricky R. SMITH, Houston, TX (US); Jiang SHI, Plano, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/193,881

(22) Filed: Aug. 19, 2008

Related U.S. Application Data
(60) Provisional application No. 60/967,674, filed on Sep. 6, 2007.

(51) Int. Cl. G01R 31/40; G05F 1/00

(52) U.S. Cl. 323/274; 324/500

(57) ABSTRACT

A system and method for determining over-voltage and under-voltage thresholds in a voltage regulator are disclosed herein. A voltage regulator includes an over-voltage detector and an under-voltage detector that determine whether the voltage regulator's regulated output voltage is above or below predetermined over-voltage and under-voltage thresholds respectively. The over-voltage detector connects to an output port that provides a signal indicating that the regulated voltage output is greater than the predetermined over-voltage threshold and not lower than the predetermined under-voltage threshold. The under-voltage detector connects to an output port that provides a signal indicating that the regulated voltage output is lower than the predetermined under-voltage threshold and not greater than the predetermined over-voltage threshold. The voltage regulator also includes an input port that provides a test signal for testing the voltage levels of the over-voltage threshold and the under-voltage threshold.

### CROSS-REFERENCE TO RELATED APPLICATIONS

The present application claims priority to U.S. provisional patent application Ser. No. 60/967,674, filed Sep. 6, 2007, and entitled “Voltage Regulator Built-In Self-Test” hereby incorporated herein by reference.

### BACKGROUND

Integrated circuits and the various systems and sub-systems therein are generally powered by one or more DC power supply voltages. In most cases, proper operation of the circuits is guaranteed only within a specified range of power supply voltages. Voltage regulators are typically employed to constrain the circuit's power supply voltages to those specified by the manufacturer as necessary for proper circuit operation. If the power supply voltages provided to the circuit drift outside the voltage range specified for proper circuit operation, the circuit may cease to function properly, or at least the circuit's proper function cannot be guaranteed.

Some voltage regulator applications benefit from having the regulator provide an alert signal to another system if the regulator's output voltage falls outside specified voltage limits. Accurate determination of the regulator's alert threshold levels is desirable.

### SUMMARY

Various systems and methods for determining over-voltage and under-voltage thresholds in a voltage regulator are disclosed herein. In accordance with at least some embodiments, a system includes an over-voltage detector and a first output port coupled to the over-voltage detector. The over-voltage detector determines whether a regulated voltage output of the voltage regulator exceeds a predetermined over-voltage threshold. The first output terminal provides an over-voltage signal generated by the over-voltage detector to a system external to the voltage regulator, the over-voltage signal indicates that the regulated voltage output is greater than the predetermined over-voltage threshold and not lower than a predetermined under-voltage threshold.

In accordance with at least some other embodiments, a method for testing a voltage regulator includes generating a test voltage varying from below a predetermined under-voltage threshold to above a predetermined over-voltage threshold in a voltage source external to a voltage regulator. The test voltage is provided to an input port of the voltage regulator to verify the under-voltage and over-voltage thresholds.

In accordance with yet other embodiments, a voltage regulator includes a first comparator that compares a voltage regulator over-voltage threshold to a test voltage generated external to the voltage regulator.

### BRIEF DESCRIPTION OF THE DRAWINGS

For a detailed description of exemplary embodiments of the invention, reference will now be made to the accompanying drawings in which:

FIG. 1 shows exemplary voltage ranges defined for a voltage regulator in accordance with various embodiments;

FIG. 2 shows a block diagram of a voltage regulator comprising over-voltage and over-voltage threshold alerts and means to verify the over-voltage and over-voltage thresholds in accordance with various embodiments;

FIG. 3 shows a flow diagram of a method for determining a voltage regulator over-voltage threshold and under-voltage threshold in accordance with various embodiments; and

FIG. 4 shows various signals employed in determining voltage regulator over-voltage and under-voltage thresholds in accordance with at least some embodiments.

### NOTATION AND NOMENCLATURE

Certain terms are used throughout the following description and claims to refer to particular system components. As one skilled in the art will appreciate, companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect or direct electrical connection. Thus, if a first device couples to a second device, that connection may be through a direct electrical connection, or through an indirect electrical connection via other devices and connections.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

The safety requirements of various applications require that a voltage regulator providing power to a system also provide alerts to the system if the voltage regulator's output voltage drifts outside of acceptable limits. A regulator can, for example, assert a signal indicating that the regulated output voltage is not within a specified operating range. A system may in turn, for example, be reset on assertion of such a signal. In order to provide such alerts, a voltage regulator can include circuitry that compares the regulated output voltage against one or more threshold voltages. The threshold voltage levels, i.e., the voltage levels at which the voltage regulator asserts alert signals can be tested for accuracy in the course of manufacturing test. Unfortunately, conventional manufacturing test methods may be ineffective at accurately determining the voltage levels at which alert signals are asserted for a variety of reasons. For example, a tester external to the voltage regulator may not be able to accurately establish the regulator internal voltages applied to generate an alert. For example, transients affecting voltages internal to the regulator may not be visible to a tester external to the regulator.

Embodiments of the present disclosure provide alerts to systems external to the regulator if a regulated output voltage is not within a predetermined voltage range. Alerts provided by embodiments of the present disclosure indicate whether a regulated output voltage is greater than a specified maximum allowable voltage, or lower than a specified minimum allowable voltage. Embodiments further provide for accurate determination of the voltage levels at which the alerts are generated by including built-in self-testing of the voltage levels, thus avoiding the measurement problems occurring with use of external testers.

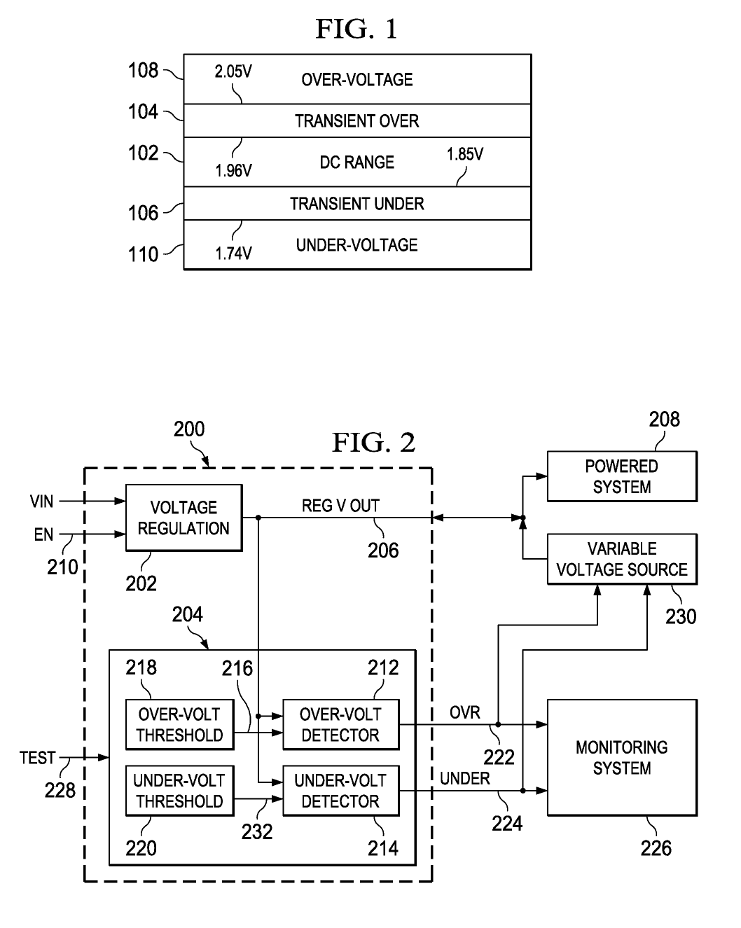

FIG. 1 shows an exemplary voltage regulator output voltage range for a nominal 1.9 volt (“V”) DC output regulator in accordance with various embodiments. The various voltages shown in FIG. 1 are for purposes of illustration. Embodiments of the present disclosure encompass a wide range of different voltages. The nominal 1.9 V output regulator generally provides a DC output voltage 102 in the range of 1.85 V to 1.96 V. Additionally, on the high side of the normal voltage band 102, a transient over-voltage band 104 is included to account for momentary transient over-voltages. Similarly, on the low side of the normal voltage band 102, a transient under-voltage band 106 is included to account for momentary transient under-voltages. Beyond the transient over-voltage and under-voltage bands 104, 106 are the over-voltage 108 and under-voltage 110 ranges. If the regulator output voltage enters either of these bands 108, 110, the regulator asserts an alert to an external system. In the exemplary voltage ranges of FIG. 1, the over-voltage and under-voltage thresholds are specified to be 2.05 V and 1.74 V respectively. As explained above, determining the actual regulator output voltages (i.e., the threshold voltages) at which over-voltage and/or under-voltage alerts are generated is problematic when using testers external to the voltage regulator. Thus, embodiments of the present disclosure include built-in self-testing of the alert thresholds.

FIG. 2 shows a block diagram of a voltage regulator 200 comprising over-voltage and over-voltage threshold alerts and means to verify the over-voltage and over-voltage thresholds in accordance with various embodiments. Various components coupled to the voltage regulator 200 are also shown. The voltage regulator 200 comprises a voltage regulation block 202 and an alert generator 204. The voltage regulation block 202 generally comprises a set of electronic components configured to maintain a constant output voltage (i.e., a regulated output voltage, REG V OUT 206) in the presence of a changing input voltage (VIN 206) and/or changing current requirements of the powered system 208. Some embodiments of the voltage regulation block 202 also include an input port through which an enable signal (EN 210) is provided. When asserted, EN 210, causes the voltage regulation block 202 to provide REG V OUT 206. The voltage regulation block 202 does not provide REG V OUT 206 if EN 210 is negated.

The alert generator 204 is coupled to the voltage regulation block 202 via the REG V OUT 206 signal. The alert generator 204 comprises an over-voltage detector 212 and an under-voltage detector 214. An over-voltage threshold generator 218 is coupled to the over-voltage threshold detector 212, and an under-voltage threshold generator 220 is coupled to the under-voltage threshold detector 214. The over-voltage detector 212 asserts an over-voltage alert signal (OVR 222) to a monitoring system 226 coupled to the regulator 200 when REG V OUT 206 exceeds the over-voltage threshold 216. Similarly, the under-voltage detector 214 asserts an under-voltage alert signal (UNDER 224) to the monitoring system 226 coupled to the regulator 200 when REG V OUT 206 is less than the under-voltage threshold 232.

The over-voltage threshold 216 and the under-voltage threshold 232 may be generated by a variety of methods. In some embodiments the threshold generators 218, 220 can employ voltage divider networks applied to a regulator 200 reference voltage.

In at least some embodiments, the over and under voltage detectors 212, 214 can be implemented as comparators that compare REG V OUT 206 to the respective over and under-voltage thresholds 216, 232.

Some embodiments provide a normal output voltage signal, that when asserted indicates that REG V OUT 206 is above the under-voltage threshold 232. Such embodiments indicate an under-voltage condition when the normal output voltage signal is negated. Some embodiments may provide a normal output voltage signal, that when asserted indicates that REG V OUT 206 is below the over-voltage threshold 216 and above the under-voltage threshold 232. Such embodiments indicate an under-voltage condition when both OVR 222 and the normal output voltage signal are negated.

The regulator 200 provides for testing of the REG V OUT 206 voltage levels at which the OVR 222 and UNDER 224 signals are asserted. As explained above, these voltage levels may not be accurately ascertained using an external tester. Consequently, voltage regulator 200 includes features for built-in self-testing of the alert thresholds 216, 232. To perform self-testing of the alert thresholds 216, 232, the voltage regulator module 202 is disabled from generating the regulated output voltage REG V OUT 206. In at least some embodiments, the REG V OUT 206 generation is disabled by negating the EN 210 signal. In some embodiments, negation of EN 210 can disable the voltage regulation module 202. In other embodiments, negation of EN 210 disables only the output of REG V OUT 206 from the voltage regulator module 206.

The alert generator 204 is enabled for testing. In at least some embodiments, the alert generator 204 is provided with a TEST 228 signal via an input port of the regulator 200. Assertion of the TEST 228 signal enables the alert generator 204 to function even if the REG V OUT 206 output voltage is disabled. An external voltage source 230 that provides a voltage varying from below the under-voltage threshold 232 to above the over-voltage threshold 216 is coupled to the voltage regulator 200 to facilitate threshold determination. As described above, the voltage regulator 200 provides a regulated DC output voltage, thus the variable voltage source 230 also provides a DC output voltage. The variable voltage source 230 is coupled to an input port (i.e., an input terminal) of the voltage regulator 200. In some embodiments, the input port to which the variable voltage source 230 is coupled is the REG V OUT 206 output port of the voltage regulator 200. In other embodiments, a different input port can be used. Embodiments of the present disclosure are not limited to any particular port.

The OVR 222 and UNDER 224 outputs of the voltage regulator 200 are also coupled to the variable voltage source 230, or to an alternative means of measuring variable voltage source 230 output. As the variable voltage source 230 sweeps its output voltage from below to above the under-voltage threshold 232, the UNDER 224 output will switch. The voltage present at the output of the variable voltage source 230 when the UNDER 224 output switches accurately represents the under-voltage threshold 232. Similarly, as the variable voltage source 230 sweeps its output voltage from below to above the over-voltage threshold 216, the OVR 222 output will switch. The voltage present at the output of the variable voltage source 230 when the OVR 222 output switches accurately represents the over-voltage threshold 216.

The variable voltage source 230 is generally a device separate from and external to the voltage regulator 200, the powered system 208, and the monitoring system 226. However, in some embodiments the variable voltage source 230 may be combined with one or more of the above listed devices. The present disclosure encompasses all such embodiments.

The voltage regulator 200, the powered system 208, and the monitoring system 226 may be combined on a single die in some embodiments. In other embodiments, one or more of the above listed devices may be manufactured as separate die. Embodiments of the present disclosure encompass all such constructions.

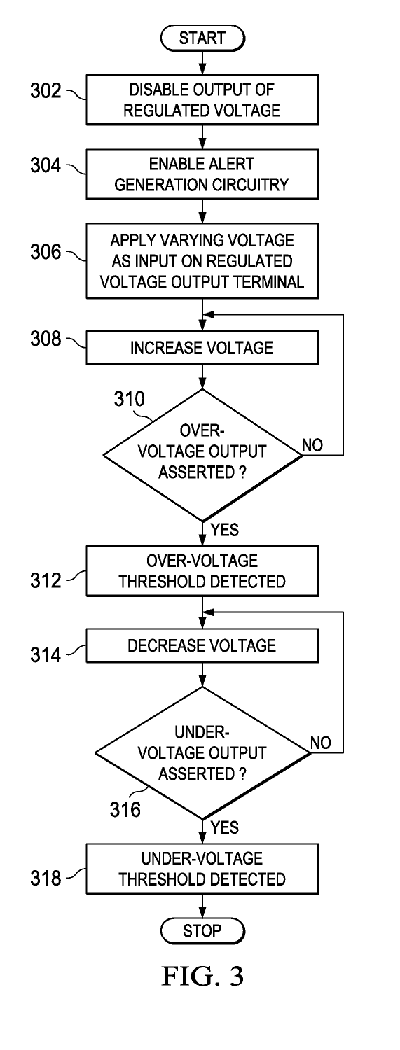

FIG. 3 shows a flow diagram of a method for determining a voltage regulator 200 over-voltage threshold 216 and under-voltage threshold 232 in accordance with various embodiments. Though depicted sequentially as a matter of convenience, at least some of the actions shown can be performed in a different order and/or performed in parallel. Additionally, some embodiments may perform only some of the actions shown. In block 302 the regulated voltage output 206 of the voltage regulator 200 is disabled. In some embodiments, only the output 206 is disabled. In other embodiments, at least a portion of the regulator circuitry 202 is disabled in addition to the regulated voltage output 206. In an embodiment that disables the alert generator 204 when the regulated voltage output 206 is disabled, the alert generator 204 is enabled in block 304. Enabling the alert generator 204 allows the alert generator 204 to continue comparing the over-voltage and under-voltage thresholds 216, 232 to a voltage provided in place of the regulated output voltage signal 206. In some embodiments, the alert generator 204 is enabled by asserting a TEST 228 signal.

In block 306, a voltage source 230 that generates a varying voltage is coupled to the voltage regulator 200. The variable voltage source 230 provides a voltage that ranges from less than the under-voltage threshold 232 to greater than the over-voltage threshold 216 of the voltage regulator 200. The variable voltage generator 230 output voltage is provided to the alert generator 204 in place of the regulated output voltage 206 for comparison against the over-voltage and under-voltage thresholds 216, 232. The variable voltage source 230 will vary its output voltage at such a rate as to allow the voltage generated at the point in time that the over-voltage or under-voltage outputs 222, 224 of the voltage regulator 200 switch, to be accurately ascertained. In some embodiments, the variable voltage generator 230 will initially provide a voltage within the expected output range 102 of the voltage regulator 200. In such a case, both the over-voltage 222 and under-voltage 224 outputs of the voltage regulator 200 are initially negated.

The variable voltage generator 230 increases its output voltage, in block 308, to produce an output voltage closer the over-voltage threshold 216. If the over-voltage output 222 of the voltage regulator 200 is asserted, in block 310, then the voltage produced by the variable voltage generator 230 is detected and recorded as the over-voltage threshold voltage 216 in block 312, and under-voltage threshold 232 determination commences in block 314. If, in block 310, the over-voltage output 222 of the voltage regulator 200 is not asserted, the output voltage of the variable voltage generator 230 is increased in block 308. The voltage increases (308) and checking for over-voltage output 222 assertion (310) continues until either an over-voltage output 222 assertion is detected or a predetermined maximum voltage is generated.

In block 314, determination of the under-voltage threshold 232 of the voltage regulator 200 begins by decreasing the output voltage of the variable voltage generator 230. If the under-voltage output 224 of the voltage regulator 200 is asserted, in block 316, then the voltage produced by the variable voltage generator 230 is detected and recorded as the under-voltage threshold voltage 232 in block 318. If, in block 316, the under-voltage output 224 of the voltage regulator 200 is not asserted the output voltage of the variable voltage generator 230 is decreased in block 314. The voltage decreases (314) and checking for under-voltage output 224 assertion (316) continues until either an under-voltage output 224 assertion is detected or a predetermined minimum voltage is generated.

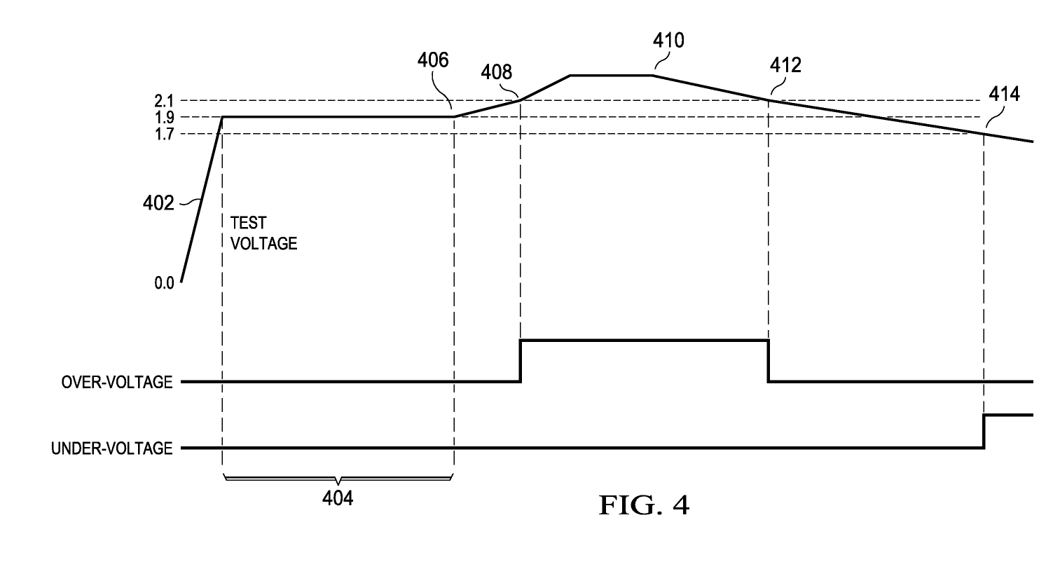

FIG. 4 shows various signals employed in determining voltage regulator 200 alert over-voltage and under-voltage thresholds 216, 232 in accordance with at least some embodiments. At 402, the variable voltage generator 230 output is ramped to 1.9 V, the nominal output voltage of the regulator 200. Prior to 402 the regulated voltage output 206 of the regulator 200 has been disabled and the alert generator module 204 has been enabled. At 404, the variable voltage generator 230 output is at 1.9 V and the over-voltage 222 and under-voltage 224 outputs are negated, indicating that the voltage supplied by the variable voltage generator 230 is not out of acceptable range. At 406, the output of the variable voltage generator 230 begins to increase. At 408 the output of the variable voltage generator 230 reaches the over-voltage threshold 216 and the over-voltage output 222 is asserted. Thus, the voltage output by the variable voltage generator 230 at 408 is an accurate representation of the over-voltage threshold voltage 216.

At 410, the output voltage of the variable voltage generator 230 begins to decrease. At 412, the output voltage of the variable voltage generator 230 falls below the over-voltage threshold 216 and the over-voltage output 222 is negated. The output voltage of the variable voltage generator 230 continues to decrease and at 414 drops below the under-voltage threshold 232 as indicated by the assertion of the under-voltage output 224. Thus, the voltage output by the variable voltage generator 230 at 414 is an accurate representation under-voltage threshold voltage 232.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A voltage regulator, comprising:
a first comparator that compares a voltage regulator over-voltage threshold to a test voltage generated external to the voltage regulator.

2. The voltage regulator of claim 1, further comprising a second comparator that compares a voltage regulator under-voltage threshold to the test voltage.

3. The voltage regulator of claim 2, further comprising a first output port that provides a signal indicating that the test voltage is greater than the over-voltage threshold and not less than the under-voltage threshold.

4. The voltage regulator of claim 2, further comprising a second output port that provides a signal indicating that the test voltage is less than the under-voltage threshold and not greater than the over-voltage threshold.

5. The voltage regulator of claim 2, further comprising an input port that couples the test voltage to the first and second comparators.

6. The voltage regulator of claim 5, wherein the input port is the regulated voltage output port of the voltage regulator.

7. The voltage regulator of claim 2 further comprising an input port coupled to the first and second comparators, wherein assertion of a signal provided by the input port enables the first and second comparators if the voltage regulator is disabled.

8. A method for testing a voltage regulator, comprising:
generating a test voltage varying from below a predetermined under-voltage threshold to above a predetermined over-voltage threshold in a voltage source external to the voltage regulator; and
providing the test voltage to an input port of the voltage regulator.

9. The method of claim 8, further comprising inhibiting the voltage regulator from providing a regulated output voltage.

10. The method of claim 8, further comprising varying the test voltage from above the predetermined over-voltage threshold to below the predetermined under-voltage threshold.

11. The method of claim 8, further comprising enabling a voltage regulator alert generator to determine whether the test voltage is above the predetermined over-voltage threshold and not below the predetermined under-voltage threshold, or whether the test voltage is below the predetermined under-voltage threshold and not above the predetermined over-voltage threshold if the voltage regulator is inhibited from providing a regulated output voltage.

12. The method of claim 11, further comprising asserting a voltage level on a voltage regulator input port to enable the voltage regulator alert generator.

13. The method of claim 8, further comprising:
determining the actual voltage regulator over-voltage threshold based, at least in part, on the value of the test voltage when the voltage regulator asserts an over-voltage signal; and
determining the actual voltage regulator under-voltage threshold based, at least in part, on the value of the test voltage when the voltage regulator asserts an under-voltage signal.

14. A voltage regulator, comprising:
an over-voltage detector that determines whether a regulated voltage output of the voltage regulator exceeds a predetermined over-voltage threshold; and
a first output port coupled to the over-voltage detector, the first output port provides an over-voltage signal generated by the over-voltage detector to a system external to the voltage regulator, the over-voltage signal indicates that the regulated voltage output is greater than the predetermined over-voltage threshold and not lower than a predetermined under-voltage threshold.

15. The voltage regulator of claim 14, further comprising:
an under-voltage detector that determines whether the regulated voltage output of the voltage regulator is below the predetermined under-voltage threshold; and
a second output port coupled to the under-voltage detector, the second output port provides an under-voltage signal generated by the under-voltage detector to the system external to the voltage regulator, the under-voltage signal indicates that the regulated voltage output is lower than the predetermined under-voltage threshold and not greater than the predetermined over-voltage threshold.

16. The voltage regulator of claim 14, further comprising an input port that provides a test signal for testing the voltage level of the over-voltage threshold and the voltage level of the under-voltage threshold.

17. The voltage regulator of claim 16, wherein the input port is a voltage regulator regulated voltage output port.

18. The voltage regulator of claim 16, wherein the test signal is provided to the over-voltage detector and to the under-voltage detector as a substitute for the regulated output voltage.

19. The voltage regulator of claim 14, further comprising an input port that provides a disable signal to the voltage regulator, wherein assertion of the disable signal disables output of the regulated voltage by the voltage regulator.

20. The voltage regulator of claim 15, further comprising an input port coupled to the over-voltage detector and to the under-voltage detector, wherein assertion of a signal provided to the input port enables the over-voltage detector and the under-voltage detector if voltage regulation is disabled.
